(19) United States
(12) Patent Application Publication
(10) Pub. No.: US 2012/0056278 A1
(43) Pub. Date: Mar. 8, 2012

(54) Method for Manufacturing Contacts for a Semiconductor Device, and Semiconductor Device Having Such Contacts

(76) Inventors: Huical Zhong, Beijing (CN); Qingqing Liang, Beijing (CN)

(21) Appl. No.: 13/201,073

(22) PCT Filed: Apr. 19, 2011
(86) PCT No.: PCT/CN11/00693

§ 371 Date: Aug. 11, 2011

(30) Foreign Application Priority Data
Jun. 22, 2010 (CN) 201010215145.5

(51) Int. Cl. H01L 29/78; H01L 29/417; H01L 21/768; B82Y 99/00

(52) U.S. Cl. 257/412; 438/637; 257/288; 977/936; 257/E21.577; 257/E29.255; 257/E29.116

(57) ABSTRACT

A manufacturing method for contacts for a semiconductor device and a semiconductor device having said contacts, said method forms contact structures whose lower part consists of a plurality of contact holes and whose upper part consists of a trench contact, said contact holes having relatively smaller diameters, and the trench contacts having relatively larger contact areas. Thus contact holes with smaller diameters and trench contacts having larger contact areas can be easily connected to the metal layer above them, thereby improving the electrical conductivity of the contacts and improving the overall performances of the device.

### CROSS REFERENCE

This application is a Section National Stage Application of, and claims priority to, International Application No. PCT/CN2011/000693, filed Apr. 20, 2011, which claims priority to Chinese Application No. 201010215145.5, filed Jun. 22, 2010. Both the PCT application and the Chinese application are incorporated herein by reference in their entireties.

### FIELD OF THE INVENTION

The present invention generally relates to a semiconductor device and a manufacturing method for the same, in particular, to a semiconductor device whose contacts have better electrical conductivity as well as a method for manufacturing contact holes for a semiconductor device whose contacts have better electrical conductivity.

### DESCRIPTION OF THE PRIOR ART

With the development of semiconductor technology, integrated circuits having better performances and more powerful functions require higher element density, and meanwhile, the dimensions or sizes of components or elements and the spaces between elements need to be further scaled down, which all pose great challenges to the manufacturing process and performances of devices. The commonly used contact structures for connecting gate electrodes and/or source/drain electrodes at present are contact holes and trench contacts, which are both made by etching through an inter-device dielectric layer and filling the obtained holes with conductive metal materials, such as W and Cu. The resistivity of such metals has been made to be as low as possible, but as the feature size decreases, it is desired for the electrical conductivity of contacts to be better and better. Accordingly, there is a need to provide contacts with better electrical conductivity and a manufacturing method for the same, so as to improve the overall performances of the device.

### SUMMARY OF THE INVENTION

The present invention provides a method for manufacturing contacts for a semiconductor device, which comprises: providing a semiconductor substrate and a semiconductor device, said device comprises a gate region and source/drain regions; forming an inter-device dielectric layer on the source/drain regions; forming a plurality of ordered holes in the inter-device dielectric layer and filling the holes to form contacts holes; forming trench contacts located on top of the contact holes and in the inter-device dielectric layer.

The present invention also provides a semiconductor device, which comprises: a semiconductor substrate; a gate region formed on the semiconductor substrate, source/drain regions formed in the semiconductor substrate on opposite sides of the gate region, and an inter-device dielectric layer formed on the source/drain regions; a plurality of ordered contact holes formed in the inter-device dielectric layer; and trench contacts formed in the inter-device dielectric layer and located on top of the contact holes.

By means of the method for manufacturing contacts according to the present invention, orderly arranged contact holes with relatively smaller diameters are formed at the lower part of source/drain contacts, and trench contacts are formed on top of the contact holes and electrically connected to upper metal layer(s). Such orderly arranged contact holes have good contact with the source/drain regions, while trench contacts thereon with relatively larger areas are easily connected to the upper layer metal, thereby improving the electrical conductivity of the contacts and the overall performances of the device.

### BRIEF DESCRIPTION OF THE DRAWINGS

FIG. 1 is a flow chart of the method for manufacturing contacts of the semiconductor device according to an embodiment of the present invention;

FIGS. 2-13 are schematic drawings of the respective manufacturing stages of contacts of the semiconductor device according to an embodiment of the present invention;

FIG. 14 is a schematic drawing of the alumina layer.

### DETAILED DESCRIPTION OF THE INVENTION

The following disclosure provides many different embodiments or examples for realizing different variations of the present invention. To simplify the disclosure of the invention, the components and configuration of specific examples are described in the following. Of course, they are merely examples and do not intend to limit the present invention. In addition, reference numbers and/or letters can be repeated in different examples in the present invention. Such repetition is for the purpose of simplification and clarity, which, in itself, does not indicate the relationship between the various embodiments and/or configurations that are discussed. Furthermore, the present invention provides examples of various specific process and materials, but those skilled in the art will be aware of the applicability of other process and/or the employment of other materials. Moreover, the structure in which the first feature being “on” the second feature as described below may include both the embodiment where the first feature is in direct contact with the second feature, and the embodiment where an additional feature is formed between the first and second features. In the latter case, the first and second features may not be in direct contact.

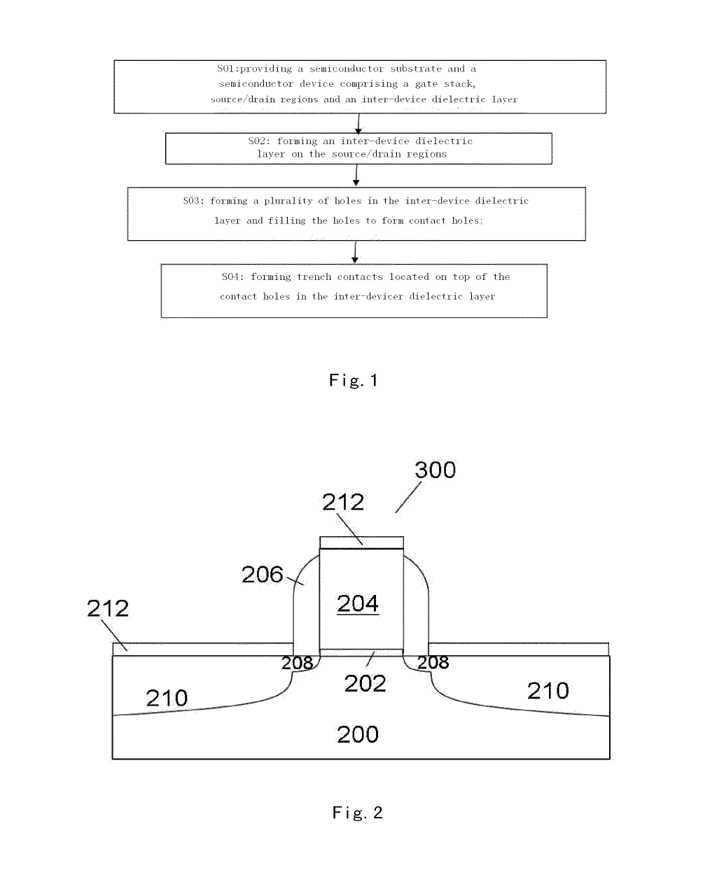

Reference is made to FIG. 1, which shows a flow chart of the method for manufacturing contacts for a semiconductor device according to an embodiment of the present invention. In step S01, a semiconductor substrate and a semiconductor device are provided, the semiconductor device comprising a gate stack and source/drain regions, as shown in FIG. 2.

In the present embodiment, the substrate 200 comprises a silicon substrate (e.g. a wafer) in a crystal structure, and optionally comprises other basic semiconductor or compound semiconductor, such as Ge, SiGe, GaAs, InP, SiC, or diamond. According to the design requirements known in the prior art (e.g. for a p-type substrate or an n-type substrate), the substrate 200 may have various doping configurations. In addition, the substrate 200 may optionally comprise an epitaxial layer, which can be strained to enhance performances, or silicon-on-insulator (SOI) structure.

The semiconductor device may be any device which comprises a gate region and source/drain regions 210, while the present invention does not limit the structure or materials of the semiconductor device or the processes or steps for its formation. FIG. 2 is a schematic drawing according to one embodiment of the semiconductor device of the present invention. A gate dielectric layer 202 and a gate electrode 204 are formed successively on the semiconductor substrate and then are patterned to form a gate region. Then, spacers 206 are formed surrounding the sidewalls of the gate dielectric layer 202 and the gate electrode 204. After forming the spacers 206, ion implantation is performed for the semiconductor substrate on both sides of the gate region to form source/drain regions 210. Before forming the source/drain regions 210, ions may be implanted into the semiconductor substrate to form source/drain shallow junctions 208. In particular, after forming the source/drain regions 210, a metal silicide layer 212 is formed in a self-alignment manner, wherein a metal is deposited on the device and annealing is performed thereafter. The metal reacts with any silicon surface in contact therewith to generate metal silicide, such as the silicon surface of the semiconductor substrate 200 where the source/drain regions 210 are located, and/or the surface of polysilicon layer of the gate electrode 204. According to the embodiment, a gate stack 300 comprising the gate dielectric layer 202, the gate electrode 204, and the metal silicide layer 212 is formed.

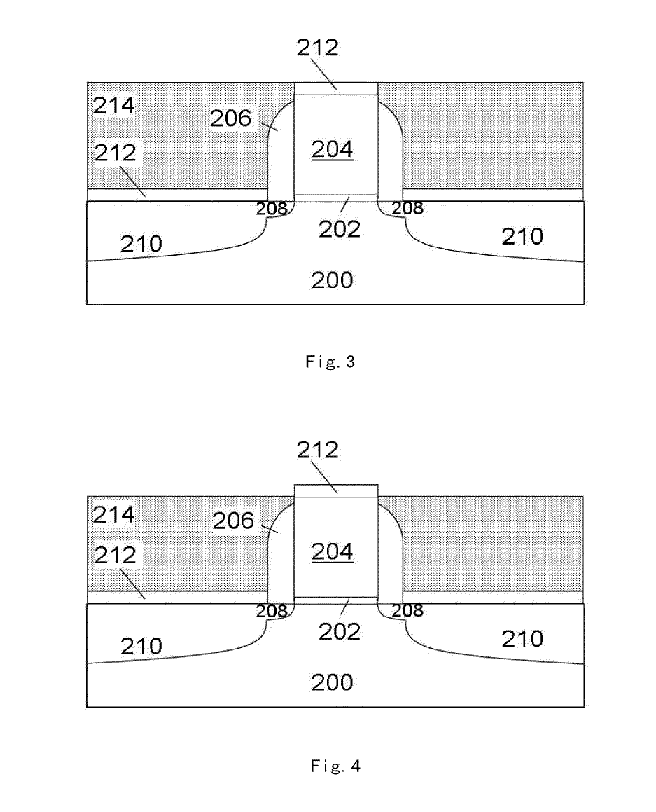

In step S02, an inter-device dielectric layer 214 is formed on the source/drain regions 210, referring to FIG. 3. First, the device is covered by a dielectric material, and then, planarization is performed to expose the upper surface of the gate stack 300, so as to form the inter-device dielectric layer 214. The dielectric material may comprise, but not limited to, for example, undoped silicon oxide (SiO₂), doped silicon oxide (e.g. borosilicate glass, boron-phosphorosilicate glass, etc.), and silicon nitride (Si₃N₄), and the combination thereof. The inter-device dielectric layer 214 may comprise a multi-layered structure and may be formed by methods including Chemical Vapor Deposition (CVD), Physical Vapor Deposition (PVD), Atomic Layer Deposition (ALD), and/or other appropriate processes.

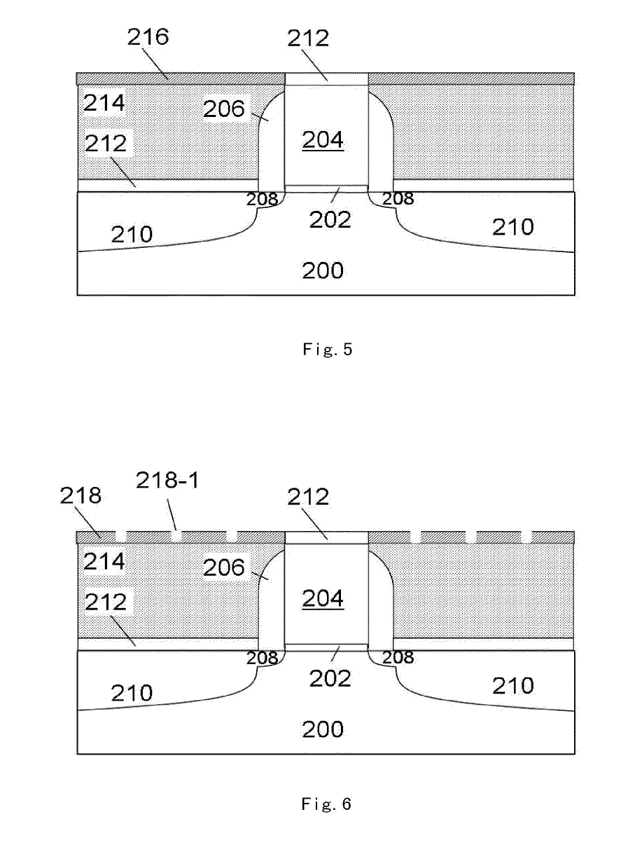

In step S03, a plurality of ordered holes 220 are formed in the inter-device dielectric layer 214, and the holes 220 are filled to form contact holes 222, as shown in FIG. 8. Specifically, first, a part of the inter-device dielectric layer 214 is removed by selective etching, so that the upper surface of the inter-device dielectric layer 214 is lower than that of the gate stack 300, as shown in FIG. 4. Subsequently, a mask having a plurality of holes is formed on the inter-device dielectric layer, and the inter-device dielectric layer is etched with the mask to form a plurality of ordered holes therein. FIGS. 5-8 show a preferred embodiment of forming the mask according to the present invention. Metallic aluminum is deposited on the device and planarization is performed to expose the upper surface of the gate stack, thereby forming a metallic aluminum layer 216 only on the inter-device dielectric layer 214, as shown in FIG. 5. Then, an Anodic Aluminum Oxide (AAO) process is performed on the device, and the metallic aluminum layer 216 is oxidized to form an alumina layer 218 having a plurality of ordered holes 218-1. As a result, the alumina layer 218 forms a mask, as shown in FIG. 6. FIG. 14 shows the structure of the alumina layer 218. The alumina layer 218 has a plurality of holes 218-1 which have uniform size and substantially the same shape, and are arranged periodically. The diameters of the holes 218-1 are about 1-60 nanometers.

In another embodiment, the mask with small diameter and small pitch holes may be formed through a complex lithographic method. In another embodiment, the mask (not shown) may be formed through an LELE (Litho-Etching Litho-Etching) process: at first, a first and a second hard mask layers are formed on the inter-device dielectric layer, and a first masking process, for example, the first exposure after applying photo resist coating, is performed; then the first hard mask layer is patterned by etching and the associated mask is removed; next, a second masking process, for example, the second exposure after applying photo resist coating, is performed; then the second hard mask layer is patterned by etching, using the first hard mask layer obtained from masking and patterning processes as a mask, and the associated mask and the first hard mask layer are removed; thereby forming a mask with small diameter and small pitch holes.

In yet another embodiment, a mask (not shown) with small diameter and small pitch holes is formed by a LFLE (Litho-Freeze Litho-Etch) method. Specifically, a hard mask layer is formed on the inter-device dielectric layer, first. A masking process is performed, including, such as, applying a photo resist layer. Then, the photo resist layer is exposed for the first time and is frozen. Subsequently, a second exposure is performed to form a mask with small aperture. Thereafter the hard mask layer is etched to form a mask with small diameter and small pitch holes.

In still another embodiment, a mask (not shown) with small diameter and small pitch holes is formed by patterning with the aid from spacers. Specifically, a hard mask layer is formed on top of the inter-device dielectric layer. Then, an auxiliary layer and spacers with regular intervals from each other are formed on the hard mask layer. Next, the auxiliary layer is removed and the hard mask layer is patterned using the spacers as mask to form a mask having a plurality of holes.

With respect to the mask having a plurality of holes formed by the above-mentioned methods, the holes are arranged periodically and have small diameters and small pitches, the diameters of the holes are about 1-60 nanometers, and the hole pitches are 1-60 nanometers.

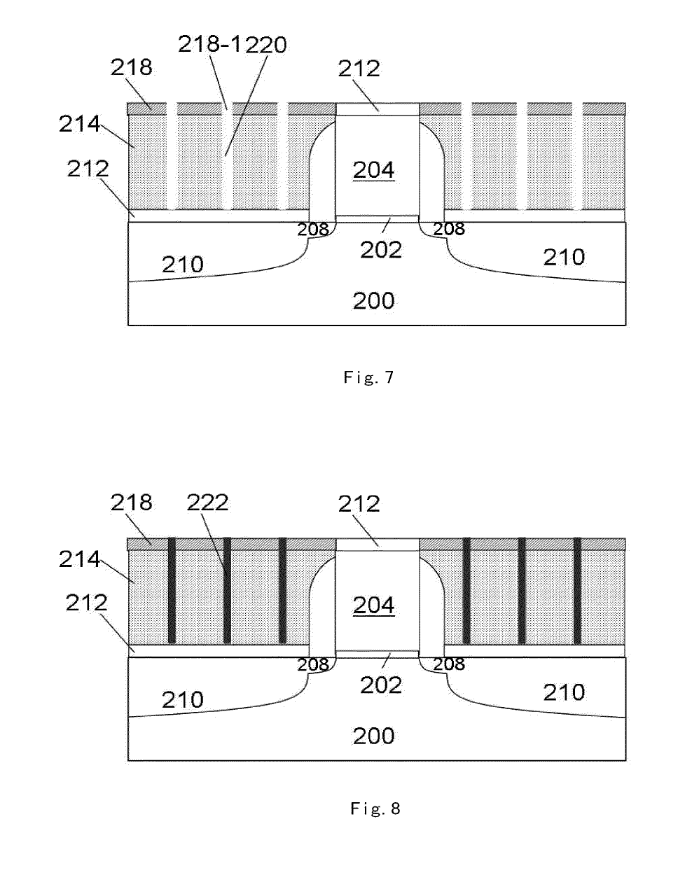

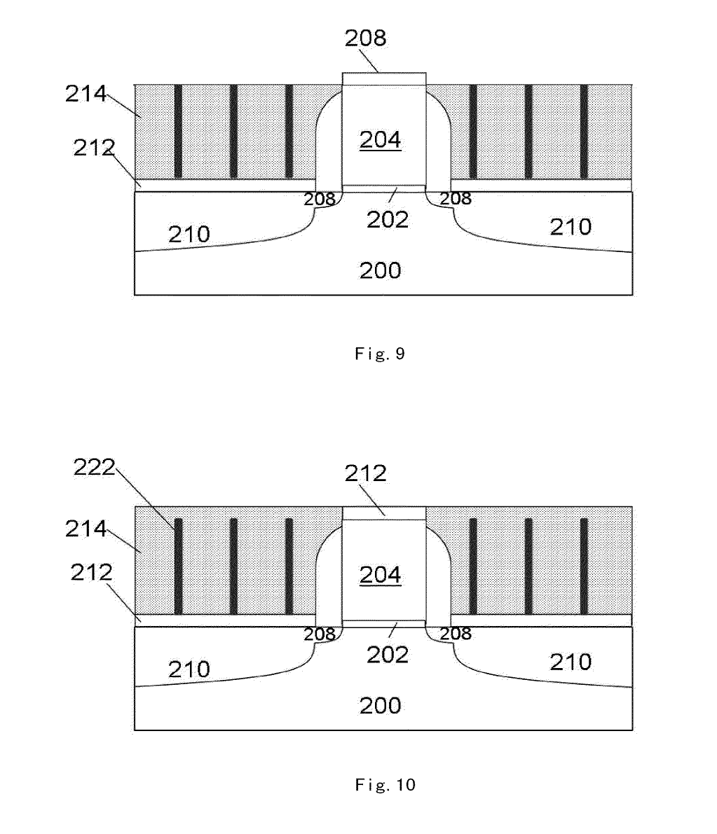

Afterwards, the inter-device dielectric layer 214 is etched to form holes 220 therein by means of etching, such as RIE, using the mask with holes through it, as shown in FIG. 7. Then, a electrically conductive material for contacts is deposited on the device to fill holes, the electrically conductive material being preferably any material of low resistivity, e.g. carbon nanotube, Cu, Ag, TiN, W, or other low resistivity materials, and planarization is performed to remove metals on the gate stack 300 and the mask, as shown in FIG. 8. Then the mask 218 is removed by selective etching to form contact holes 222 with the holes 220 filled, as shown in FIG. 9. In a preferred embodiment, orderly arranged contact holes made of nanotube or nanowire with small diameters are formed by the above-mentioned methods, and the contact holes made of nanotube or nanowire are highly conductive to realize good contact with the source/drain regions.

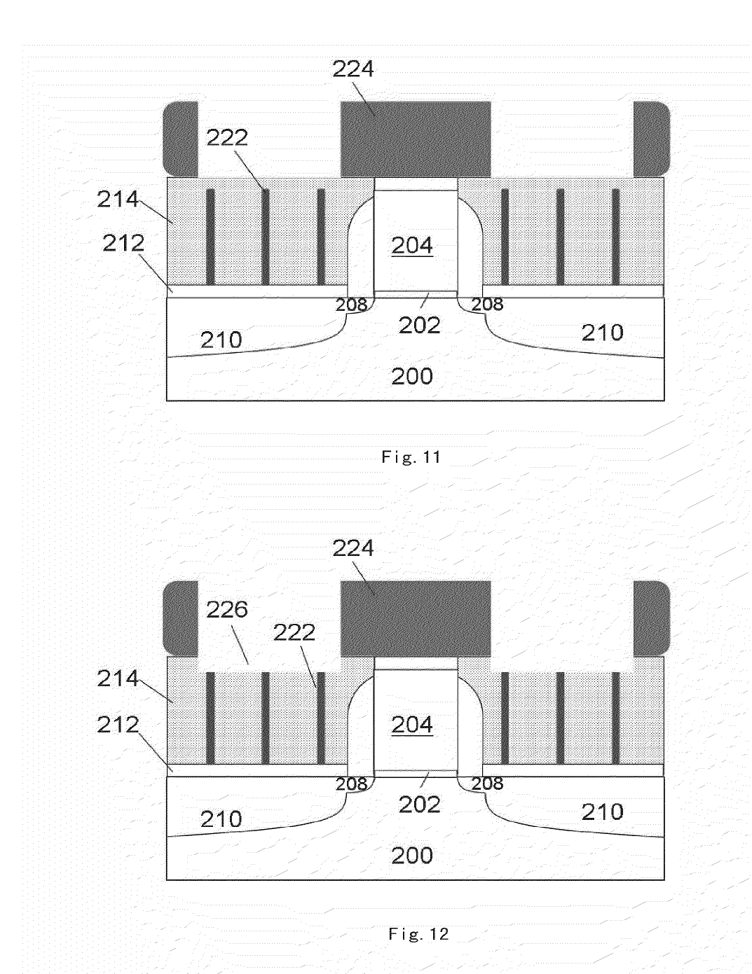

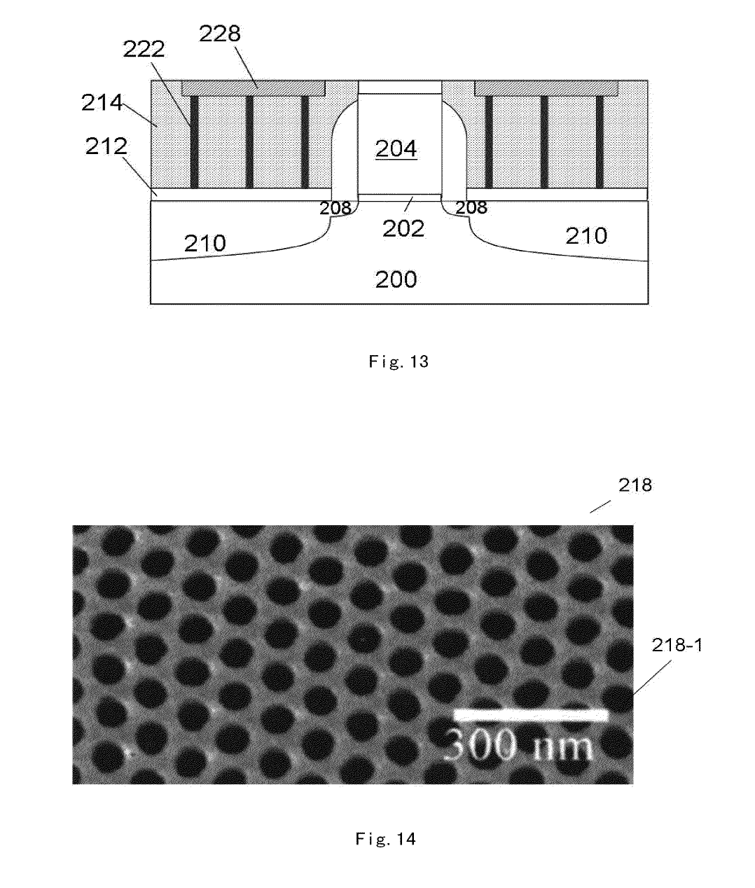

In step S04, trench contacts 228 located on top of the contact holes 222 is formed in the inter-device dielectric layer 214, as shown in FIG. 13. Specifically, first, a layer of dielectric material is deposited on the device, which may be the same as or different from the material of the inter-device dielectric layer 214. The dielectric material may be, but not limited to, for example, undoped silicon oxide (SiO₂), doped silicon oxide (e.g. borosilicate glass, boron-phosphorosilicate glass, etc.), and silicon nitride (Si₃N₄), and a combination thereof. Then, planarization, such as CMP, is performed until the upper surface of the gate stack 300 is exposed, so that the upper surface of the inter-device dielectric layer 214 is substantially flush with the upper surface of the gate stack 300, as shown in FIG. 10. Next, a masking process 224 is performed on the device, the openings of the mask 224 correspond to the trench contacts to be formed, as shown in FIG. 11, and the number of the openings of the mask 224 can be one or more as desired, thereby forming trench contacts having one or more trench structures correspondingly. Afterwards, selective etching is performed by, for example, RIE, to form trenches 226 in the inter-device dielectric layer 214, with the contact holes 222 used as a stopper layer, as shown in FIG. 12. Then, the mask 224 is removed and an electrically conductive material is deposited on the device, which is preferably a low resistivity material, such as Cu, Ag, TiN, W, or other materials with low electrical resistivity, and planarization is performed to remove the electrically conductive material on the gate stack 300 and the inter-device dielectric layer 214 to form trench contacts 228, as shown in FIG. 13. As a result, contact structures whose lower parts each consist of contact holes 222 and whose upper parts each consist of a trench contact 228 are formed.

According to a manufacturing method in one embodiment of the present invention, contact structures whose lower parts each consist of a plurality of ordered contact holes and whose upper parts each consist of the trench contact are formed on the source/drain regions. Contacts of such structures, whose lower parts in contact with source/drain regions each include contact holes of small diameters and whose upper parts each include a trench contact having larger contact areas, have better electrical conductivity and can be easily electrically connected to upper metal layer(s), thereby improving the electrical conductivity of contacts and improving the overall performances of the device.

The present invention also provides a semiconductor device having contacts formed by the above methods, as shown in FIG. 13. FIG. 13 shows a schematic drawing of the semiconductor device structure according to one embodiment of the present invention, the device comprising: a semiconductor substrate 200; a gate region 202, 204 formed on the semiconductor substrate 200; source/drain regions 210 formed in the semiconductor substrate 200 on opposite sides of the gate region 202, 204; an inter-device dielectric layer 214 formed on the source/drain regions 210; a plurality of ordered contact holes 222 formed in the inter-device dielectric layer 214; and trench contacts 228 formed in the inter-device dielectric layer 214 and located on top of the contact holes 222. The contact holes 222 have diameters of 1-60 nm, and the material of the contact holes 222 may be carbon nanotube, Cu, Ag, TiN, W, or other materials. The semiconductor device has contact structures whose lower parts each consist of contact holes and whose upper parts each consist of a trench contact. Contacts of such structure, whose lower parts in contact with source/drain regions each consist of a plurality of ordered contact holes of relatively smaller diameters and whose upper parts each consist of a trench contact having relatively larger contact area, have better electrical conductivity and can be easily electrically connected to upper metal layer(s), thereby improving the electrical conductivity of the device and improving the overall performances of the device.

Although the example embodiments and the advantages thereof have been described in detail, it shall be understood that various changes, substitutions and modifications can be made to the embodiments without departing from the spirit of the invention and the protection scope defined by the appended claims. As for other examples, those ordinarily skilled in the art shall easily understand that the sequence of the process steps may be changed without departing from the protection scope of the present invention.

In addition, the application of the present invention is not limited to the techniques, mechanisms, fabrication, compositions, means, methods and steps in the specific embodiments described in the description. On the basis of the disclosure of the present invention, those ordinarily skilled in the art shall easily understand that the existing or to be developed techniques, mechanisms, fabrication, compositions, means, methods and steps, which have substantially the same function or achieve substantially the same effect as the respective embodiments described in the present invention, can also be used according to the present invention. Therefore, the appended claims intend to include such techniques, mechanisms, fabrication, compositions, means, methods and steps in the protection scope thereof.

1. A method for manufacturing contacts for a semiconductor device, comprising:
a) providing a semiconductor substrate and a semiconductor device, said device comprising a gate region and source/drain regions;
b) forming an inter-device dielectric layer on the source/drain regions;
c) forming a plurality of ordered holes in the inter-device dielectric layer and filling the holes to form contact holes; and
d) forming trench contacts located on top of the contact holes and in the inter-device dielectric layer.

2. The method according to claim 1, wherein the step of forming the holes in step c comprises: forming a mask having a plurality of ordered holes on the inter-device dielectric layer; and etching the inter-device dielectric layer through the mask to form a plurality of ordered holes in the inter-device dielectric layer.

3. The method according to claim 2, wherein the step of forming the mask comprises: forming a metallic aluminum layer on the inter-device dielectric layer, oxidizing the metallic aluminum layer to form an alumina layer having a plurality of holes, and using the alumina layer as the mask.

4. The method according to claim 2, wherein the step of forming the mask comprises: forming a second hard mask layer and a first hard mask layer successively on the inter-device dielectric layer; forming a patterned first hard mask layer through a first masking process; and forming a patterned second hard mask layer through a second masking process and the patterned first hard mask layer, thereby forming the mask having the plurality of holes.

5. The method according to claim 2, wherein the step of forming the mask comprises: forming a hard mask layer on the inter-device dielectric layer; and patterning the hard mask layer by masking and exposing the mask twice, thereby forming the mask having the plurality of holes.

6. The method according to claim 2, wherein the step of forming the mask comprises: forming a hard mask layer on the inter-device dielectric layer; forming an auxiliary layer and spacers for the auxiliary layer, which are with regular intervals from each other, on the hard mask layer; removing the auxiliary layer and patterning the hard mask layer by using the spacers as a mask, thereby forming the mask having the plurality of holes.

7. The method according to claim 1, wherein the holes are substantially arranged periodically and have substantially the same shape.

8. The method according to claim 1, wherein the diameters of the holes are 1-60 nm.

9. The method according to claim 1, wherein the pitches between the holes are 1-60 nm.

10. The method according to claim 1, wherein, between steps a and b, there is the step of forming a metal silicide layer or an electrically conductive material contact layer on the source/drain regions.

11. The method according to claim 1, wherein the material of the contact holes includes carbon nanotube, Cu, Ag, TiN, or W.

12. The method according to claim 1, wherein the trench contacts have one or more trench structures.

13. A semiconductor device, which comprises:
a semiconductor substrate;
a gate region formed on the semiconductor substrate, source/drain regions formed in the semiconductor substrate on opposite sides of the gate region, and an inter-device dielectric layer formed on the source/drain regions;
a plurality of ordered contact holes formed in the inter-device dielectric layer; and
trench contacts formed in the inter-device dielectric layer and located on top of the contact holes.

14. The semiconductor device according to claim 13, wherein the device further comprises a metal silicide layer or an electrically conductive material contact layer formed on a part of semiconductor substrate including the source region and the drain region.

15. The semiconductor device according to claim 13, wherein the diameter of the contact holes is 1-60 nm.

16. The semiconductor device according to claim 13, wherein the plurality of contact holes are substantially arranged periodically and have substantially the same shape.

17. The semiconductor device according to claim 13, wherein the material of the contact holes includes carbon nanotube, Cu, Ag, TiN, or W.

18. The semiconductor device according to claim 13, wherein the trench contacts have one or more trench structures.
